(19) United States
(12) Patent Application Publication
(10) Pub. No.: US 2014/0078694 A1
(43) Pub. Date: Mar. 20, 2014

(54) Mobile Wristwatch comprising several electrical and micro mechanical components that acts as a central unit for a variety of tasks

(71) Applicant: Stanley Gunnar Emanuel Wissmar, Jarfalla (SE)

(72) Inventor: Stanley Gunnar Emanuel Wissmar, Jarfalla (SE)

(21) Appl. No.: 14/116,160

(22) PCT Filed: May 24, 2012
(86) PCT No.: PCT/SE2012/000082

§ 371 Date: Nov. 7, 2013

(30) Foreign Application Priority Data
May 26, 2011 (SE) 1100422-3

(51) Int. Cl. H05K 7/06

(52) U.S. Cl. CPC H05K 7/06
USPC 361/749

(57) ABSTRACT

The present invention relates to a mobile wrist watch, in particular to such an accessory comprising several electrical- and micromechanical components acting as a central processing unit for a multitude of tasks including mobile computing, imaging handling, medical monitoring and as a multiple sensor device communicating with far and nearby electronic devices wirelessly with established radiofrequency (i.e. GSM, bluetooth etc.) technologies.

### TECHNICAL FIELD OF THE INVENTION

The present invention relates to a mobile wrist watch, in particular to such an accessorie comprising several electrical- and micromechanical components acting as a central processing unit for a multitude of tasks including mobile computing, imaging handling, medical monitoring and as a multiple sensor device communicating with far and nearby electronic devices wirelessly with established radiofrequency (i.e. GSM, bluetooth etc.) technologies.

### BACKGROUND OF THE INVENTION

“The Use of Murata Ceramic Bluetooth Antenna for Wrist Device Based on Flexible Printed Circuit Boards; A. Zhao, J. Xue, C. Jing and A. Salo; Proceedings of the 38th European Microwave Conference, 2008. A wrist device made of a flexible printed circuit board having bluetooth communication.

U.S. Pat. No. 2003081506 A1 describes a wrist watch phone where electrical components are mounted in a metallic case/housing.

U.S. Pat. No. 6,035,035 describes a wrist-mounted phone device comprising a phone mechanism and a battery source.

U.S. Pat. No. US2010112964 describes a wrist watch with a mobile terminal with a metal housing connected with a band or strap.

German Pat. No. DE102008027746 describes a wrist-watch arrangement comprising a clock, a bracelet, with which the clock is connected, a mobile telephone unit, a projection unit and a camera.

U.S. Pat. No. US2009069045 describes a wrist-watch mobile phone device which is recharged by body temperature.

Japanese Pat. No. JP2002152327 describes a structure of an electronic wrist watch having functions of communicating with a mobile telephone set to operate this.

U.S. Pat. No. 2010146463 describes a watch phone and a method for handling an incoming call using the watch phone.

“Detecting Vital Signs with WearableWireless Sensors, Review”; T. Yilmaz, R. Foster and Y. Hao; Sensors 2010, 10, 10837-10862; describes how on-body sensor design can enable change in the conventional health-care system.

LG-GD910 Watch phone has a 1.4-inch touchscreen, text-to-speech capability, Wi-Fi and Bluetooth radio and a music player and is water resistant.

W Phonewatch from Kempler & Strauss combines a touchscreen interface with basic phone functionality.

Citizen CH-606 is a wrist measuring Automatic Portable Blood Pressure Monitor.

SomnoMedics “Somno Watch is a medical devices for sleep diagnostics and sleep therapy.

Catsys Tremor is a medical device for tremor diagnostics.

Citizen Eco-Drive Thermo use the temperature difference between the wearer's arm and the surrounding environment as a power source.

None of these solves the problem of utilizing the metallic case and link chain (i.e. strap or band) collectively as a whole electronic and thermal circuit together with its packaged electronic components, integrating and packaging the latter inside the former in an optimal fashion from a user's perspective for a multiple range of applications:
(i). Steer and interact with the functions of electronic devices which are in the users immediate vicinity.
(ii). Identification—to use instead of an ordinary security pass card
(iii). Electronic payment—to use instead of an existing credit card
(iv). For continuous measurement and diagnosis of a users health state
(v). For blind persons—to improve real-time communication with braisse language.
(vi). Mobile Gaming—using the medical sensors and steering devices to interact in a virtual world

### SUMMARY OF THE INVENTION

The present invention addresses the above and other needs by overcoming the disadvantages enumerated above, and also allows additional degrees of physical latitude when communicating electronically with other electronic devices allowing the user to use his or her hand for something else than holding the electronic device.

Another objective of the invention is to provide an alternative use of a wrist watch apart from being an esthetical and/or cultural valued item.

This object is met by the invention as defined in the independent claims. Specific embodiments of the invention are defined in the dependent claims. In addition, the present invention has other advantages and features apparent from the description below.

The present invention is based on the understanding that an alternative packaging design, compared to an established laptop computer or smartphone, achieves similar functionalities but can be mounted on to the users wrist, having an exterior design and esthetical appearance similar to an ordinary wrist watch but, combined with its interior design, have electromechanical and electromagnetic properties which allows the user full access to it and at the same time allowing a higher degree of physical latitude.

According to a first aspect of the present invention, there is an exterior made up of a metallic case and links. Where the links are made up of a multitude of metallic parts which are connected in the horizontal direction mechanically and in the vertical/radial direction magnetically; allowing the interior to be fully integrated and packaged by the aforementioned exterior case and links. By having the upper row of semi-circled shaped metallic parts obtain magnetic properties (or alternating the magnetic polarity of the respective metal links placed adjacently) the neighbouring parts can position with different angles respective to each other; consequently the whole metallic link can obtain a final shape similar to a partial circle (i.e. similar shape as a wrist watch when mounted on user's wrist but with the significant difference of being made up of two rows of metallic links instead of one).

There is further provided a rigid-flex printed circuit board, placed inside the metallic case and links, in order to mount electrical components and electrically connect them to each other making up the core of the interior electrical circuit.

Apart from having a battery as energy source or a thermoelectric circuit an additional source is to add a layer, alongside the rigid-flex printed circuit board, of conformal coating consisting of a piezoelectric material which converts mechanical energy to electrical energy, providing additional electricity to the electrical components.

In another embodiment of the present invention, there is provided a rigid, slightly curved cantilever beam; which at one end is fixated to the above mentioned exterior case and at the other end free standing. The free standing end of the cantilever beam has an accelerometer mounted on it in order to monitor the user's tremor movement of his or her hand.

Thus it can be used for monitoring tremor movements for medical diagnostics and/or gaming/steering devices and/or software available to the user. Further, when not used for the above monitoring hand tremor/movements, the accelerometer can be used for monitoring arm movements for example, various gaming applications.

In another embodiment of the present invention, there is attached a medical sensor on the backside of the metallic link described above. Its purpose is to detect glucose levels from the interstitial fluid in the subcutaneous tissue under the skin. The medical sensor is placed in an opening in the centre of a transdermal tape.

In another embodiment of the present invention, there is provided at one side of the metallic case a viewfinder display placed in the metallic link facing outwards. Subsequently, an image camera sensor is located on the adjacent side of the metallic case (or at its end) placed in the metallic link facing outwards.

Additionally, on top of the image sensor an objective lens can be mounted (screwed) or fixated magnetically when more advanced photography or filming is needed. When not using the objective lens it can either be (i). placed elsewhere (pocket etc.) or, (ii). fixated to an arm which can revolve around its (other) end—which is fixated to the metallic link—with more than a 200 degrees angle in order to place it in a protective position partly inside the metallic link.

Further, in order to enhance the user a higher degree of physical latitude when taking photos or filming, the viewfinder can be mounted mechanically on an exterior module which can be moved along the metallic link.

In another embodiment of the present invention, there is a projection device mounted at one end of the metallic case in order for the user to project images onto for the moment available physical areas (walls, floor, table etc.) when, for example, having a mobile video conversation.

In another embodiment of the present invention, there is provided a sensor at the end of the rigid-flex printed circuit board placed underneath the user's blood veins at the wrist facing inwards. Thus the users pulse can be monitored continuously for medical or health purposes. Alternatively, when using the above described viewfinder and image sensor for photography or filming the pressure sensor can function as a snapshot/recording button (automatically adjusted to such usage by software alterations) handled by the users other hand's thumb (for example).

In another embodiment of the present invention, there is provided a top display located in the centre of the metallic case facing outwards. It constitutes of three different kinds of polymers, from top to bottom: (i). a shape memory polymer (or an electro active polymer) (ii). a lenticular lens polymer and (iii). organic light emitting diode (oled) polymer.

Combining, or separately, the functionalities of the above described layers of polymers offers a wide range of physical shapes and images which can simultaneously be created resulting in an increased esthetic user experience. The shape memory polymer can further be used to display Braille symbols in order for blind people to receive realtime communication information.

### BRIEF DESCRIPTION OF THE DRAWINGS

The above, as well as additional objects, features and advantages of the present invention, will be better understood through the following illustrative and non-limiting detailed description of preferred embodiments of the present invention, with reference to the appended drawings, wherein the same reference numerals are used for similar elements, and in which:

FIG. 1 is a schematic top view of the mobile wrist watch where the electronic components are mounted on a flexible printed circuit board packaged inside the metallic case and links in accordance with an embodiment of the present invention.

FIG. 2 is a schematic top and profile view of the metallic case and links in accordance with an embodiment of the present invention.

FIG. 3 is a schematic profile view of the metallic case, links and plastic film placed on one side in accordance with an embodiment of the present invention.

FIG. 4 a and b are a schematic top and profile view of the rigid-flex printed circuit board mounted and packaged inside the metallic case and links and plastic film in accordance with an embodiment of the present invention.

FIG. 5 a, b and c are a schematic top and profile view of the conductive layers integrated in the rigid-flex printed circuit board mounted and packaged inside the metallic case and links in accordance with an embodiment of the present invention.

FIG. 6 a and b are a schematic profile view of the mobile wrist watch, where the metallic links are formed to enclose the user's wrist, and the electronic components are mounted on a rigid-flex printed circuit board packaged inside the metallic case and links in accordance with an embodiment of the present invention.

FIG. 7 a and b is a profile view of the metallic links with two alternative combinations of the same with- and without magnetic properties, in accordance with an embodiment of the present invention.

FIG. 8 is a schematic top and profile view of the components mounted on the rigid-flex printed circuit board and packaged inside the metallic case and links in accordance with an embodiment of the present invention.

FIG. 9 is a schematic profile view of the mobile wrist watch, where the metallic links are formed to enclose the user's wrist, and where the viewfinder display is placed in the metallic link facing outwards and the image camera sensor is located on the adjacent side, along with optics; in accordance with an embodiment of the present invention.

FIG. 10 is a schematic profile view of the mobile wrist watch, where the image camera sensor has optics mounted on top of it, where the latter is fixated to an arm which revolves around its other end, which there is fixated to the metallic link; in accordance with an embodiment of the present invention.

FIG. 11 is a schematic profile view of the mobile wrist watch, where the optics is placed in a protective position, partly inside the metallic link; in accordance with an embodiment of the present invention.

FIG. 12a is a schematic profile view of how the viewfinder and image sensor is mounted on an exterior module which is electrically connected to the electrical circuit by a rollable flexible printed circuit board and shielded by a metallic roof which is fixated to the metallic case or link; in accordance with an embodiment of the present invention.

FIG. 12b is a schematic profile view of how the viewfinder and image sensor, mounted on an exterior module and electrically connected to the electrical circuit by a rollable flexible printed circuit board, is extended to its end position along the metallic links; in accordance with an embodiment of the present invention.

FIG. 13a is a schematic profile view of the piezoelectric conformal coating placed on one side of the rigid-flex printed circuit board and connected to the same in accordance with an embodiment of the present invention.

FIG. 13b is a narrow schematic profile view of the piezoelectric conformal coating placed on one side of the rigid-flex printed circuit board and connected to the same in accordance with an embodiment of the present invention.

FIG. 13c is a narrow schematic profile view of the piezoelectric conformal coating placed on one side of the rigid-flex printed circuit board and connected to the same in accordance with an embodiment of the present invention.

FIG. 14a is a schematic profile view of the mobile wrist watch with a medical sensor placed on the inner exterior of the metallic link in accordance with an embodiment of the present invention.

FIG. 14b is a narrow schematic profile view of the mobile wrist watch with a medical sensor placed on the inner exterior of the metallic link in accordance with an embodiment of the present invention.

FIG. 15a is a schematic profile view of the metallic case and the top display constituted of different kinds of polymers: a shape memory-, a lenticular lens- and an organic light emitting diode polymer in accordance with an embodiment of the present invention.

FIG. 15b is a schematic profile view of the metallic case and the top display showing the top polymer layer, a shape memory polymer, changing topography shape in accordance with an embodiment of the present invention.

FIG. 16a is a schematic top view of the cantilever beam with an accelerometer mounted on its end in accordance with an embodiment of the present invention.

FIG. 16b is a schematic profile view of the conductive layers inside the flexible printed circuit board mounted on the cantilever beam electrically connecting the accelerometer and the remaining electronics in accordance with an embodiment of the present invention.

FIG. 17 is a schematic profile view of a non-metallic, bendable material which encapsulates the electronic components mounted on the rigid-flex printed circuit board all the while obtaining a final shape similar to a partial circle in accordance with an embodiment of the present invention.

FIG. 18a is a schematic profile view of at least one conductive layer which end acts as a heat spreader which the thermoelectric generator (TEG) is mounted on top of and in turn on top of the latter the metallic case 1 is locally formed inwards in order to thermally connect to the TEG in accordance with an embodiment of the present invention.

FIG. 18b is a schematic profile view of the thermoelectric generator (TEG) mounted or integrated on top of each individual electronic component, where the latter functions as the heat source. On the other, top side the metallic link is locally formed inwards in order to thermally connect and function as the cold source for the thermoelectric generator (TEG) in accordance with an embodiment of the present invention.

### DETAILED DESCRIPTION OF EMBODIMENTS OF THE INVENTION

The following description is of the best mode presently contemplated for carrying out the invention. This description is not to be taken in a limiting sense, but is made merely for the purpose of describing the general principles of the invention. The scope of the invention should be determined with reference to the claims.

The present invention is based on the understanding that an alternative packaging design, compared to an established laptop computer or Smartphone, achieves similar functionalities but can be mounted on to the users wrist, having an exterior design and esthetical appearance similar to an ordinary wrist watch but, combined with its interior design, have electromechanical and electromagnetic properties which allows the user full access to it and at the same time allowing a higher degree of physical latitude.

The mobile wrist watch functions as an established laptop computer, medical device and/or Smartphone but is mounted on to the user's wrist.

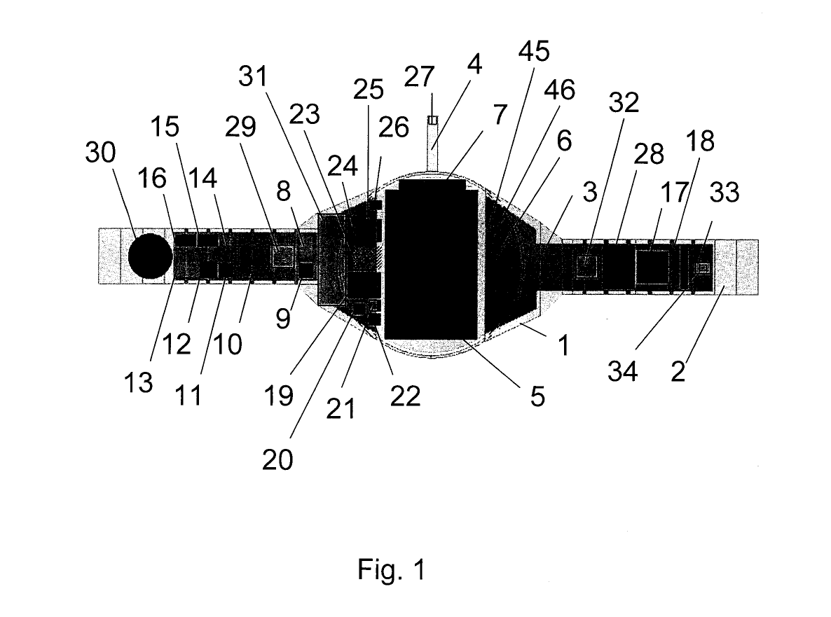

With reference to FIG. 1, a first embodiment of the present invention is a metallic case 1, embodying the central part of the mobile wrist watch. The metallic case 1 is flanked by metallic links 2 on either side. The metallic case 1 and metallic links 2 are comprised of a rigid-flex printed circuit board 3. Fixated to the metallic case 1 is a rigid, slightly curved cantilever beam 4.

In this embodiment, the printed circuit board 3 has different electronic components mounted on it: a battery 5; a micro SIM card 6; an antenna 7; a flash memory 8; an audio codec 9; a CPU 10; a power management IC 11; a transceiver 12; power amplifiers 13, 14, 15 and 16, a flash memory 17; a WLAN IC 18; a digital baseband processor 19; a GPS IC 20; a touch screen controller 21; a display interface 22; a flash memory 23; an accelerometer 24; a power management IC 25; a battery charger/usb controller 26; a thermoelectric generator (TEG) 45; and a power converter 46.

In this embodiment, there is also on the rigid, slightly curved cantilever beam 4 an accelerometer 27 mounted and electrically connected to the rigid-flex printed circuit board 3.

In this embodiment, placed on flanking sides of the metallic case 1, are a viewfinder display 28 and an image sensor 29; and, on the same side as the image sensor 29 is an optics lens module 30 mounted.

In this embodiment, placed within the boundary of the metallic case 1 is a projection module 31 and along the metallic link is an image sensor 32 placed.

In this embodiment, at the end of the metallic link 2 is a pressure- or infrared sensor 33 placed together with an accompanying membrane 34 which enhances its sensitivity.

This constitutes the parts of the electronic circuit which are electrically connected by the rigid-flex printed circuit board 3.

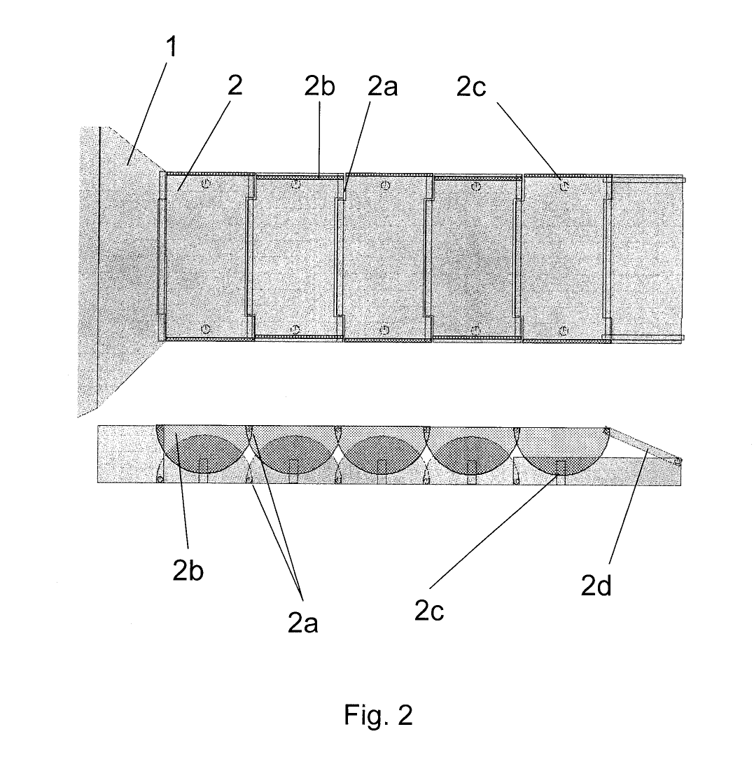

With reference to FIG. 2, in this embodiment the metallic links 2 are made up of a multitude of metallic parts: there are metallic pins 2a which connect the respective metallic link 2 together in the horizontal direction mechanically. In the vertical direction there are semi-circled metallic parts 2b which obtain magnetic properties in order to physically (and electrically) connect vertically the upper and lower rows of the metallic links 2 in order for the neighbouring parts to position with different angles respective to each other; consequently the whole metallic link 2 chain can obtain a final shape similar to a partial circle (i.e. similar shape as a wrist watch when mounted on user's wrist).

In this embodiment, there are further metallic pins 2c placed inside the metallic link 2 in the vertical direction in order to both fixate the rigid-flex printed circuit board 3 and electrically and/or thermally connect the electronic circuit described above with the metallic- case 1 and link 2 chains.

In this embodiment, there is further as the end part of the metallic link 2 chains a metallic top 2d which is fixated at one end and at the other end can be opened or locked.

In this embodiment, the metallic- case 1 and link 2 chains can obtain a plastic surface finish (not shown) by, for example, injection moulding to attain the users desired esthetical shape and appearance.

In this embodiment, as a complement or alternative, there are a multitude of square shaped rings (not shown) enclosing alongside the completed (two rows) metallic link chain, which can move freely along the length only bounded by pegs on both sides; ultimately to ensure the required encapsulation.

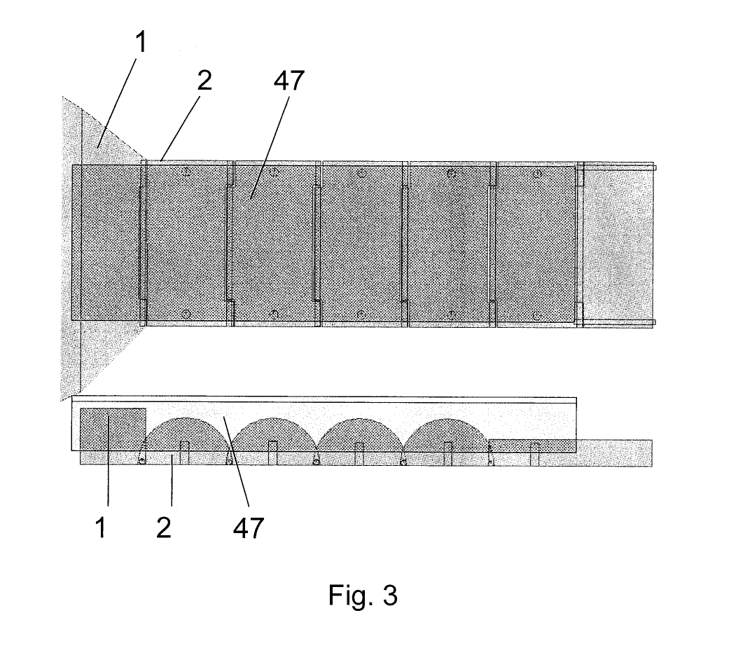

With reference to FIG. 3, in this embodiment the metallic links 2 have a plastic film 47 placed on its interior side stretched along the metallic links 2 accumulated length ending inside the metallic case 1. The plastic, adhesive film's function is to waterproof electrical components. The plastic film 47 is constituted of a polymer material and could be in a form of a bag.

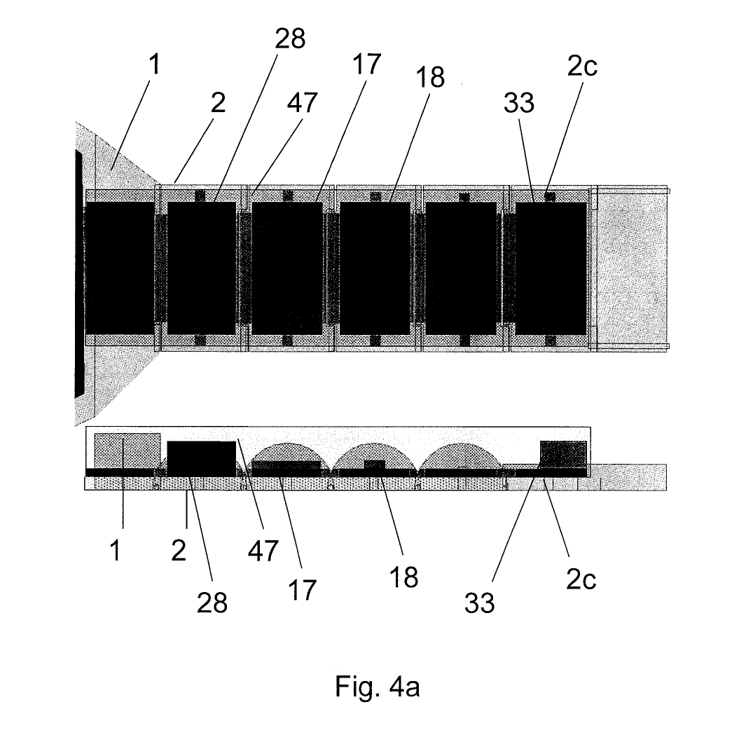

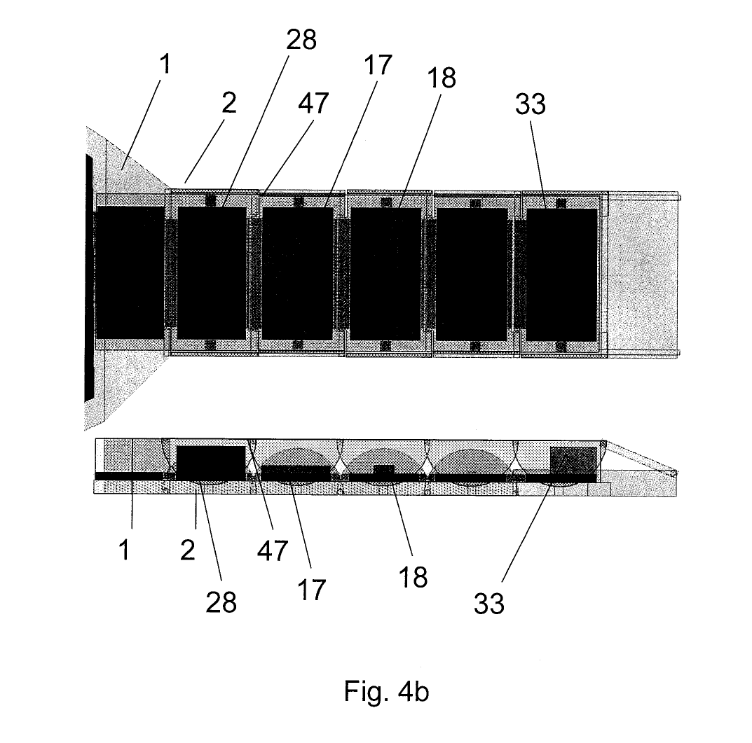

With reference to FIG. 4 a and b, in this embodiment the rigid-flex printed circuit board 3, and its mounted above mentioned electrical components, are placed on the bottom half of the metallic case 1 and links 2, and the plastic, adhesive film 47. The rigid-flex printed circuit board 3 is mechanically fixated to the metallic link 2 by having along its edges holes patterned matched to the above mentioned metallic pins 2c, where the latter have a direction ninety (90) degrees (upwards) in relation to the former.

Subsequently, the rigid-flex printed circuit board 3 and its mounted electrical components (which do not need to interface with the exterior) are enclosed by the plastic, adhesive film 47 on all sides but the one facing the metallic case 1. On the side facing the metallic case 1, the plastic, adhesive film 47 is pressed together vertically in such a way to be mechanically in contact with the flexible film—which is part of the rigid-flex printed circuit board 3—and thus enclose the latter and its mounted electrical components. The enclosure protects the electrical components from water, moisture and dust/unwanted particles.

Subsequently, the top half of the metallic case 1 and links 2 are mechanically and magnetically connected uniting the opposing sides into a complete metallic casing and adjoining links.

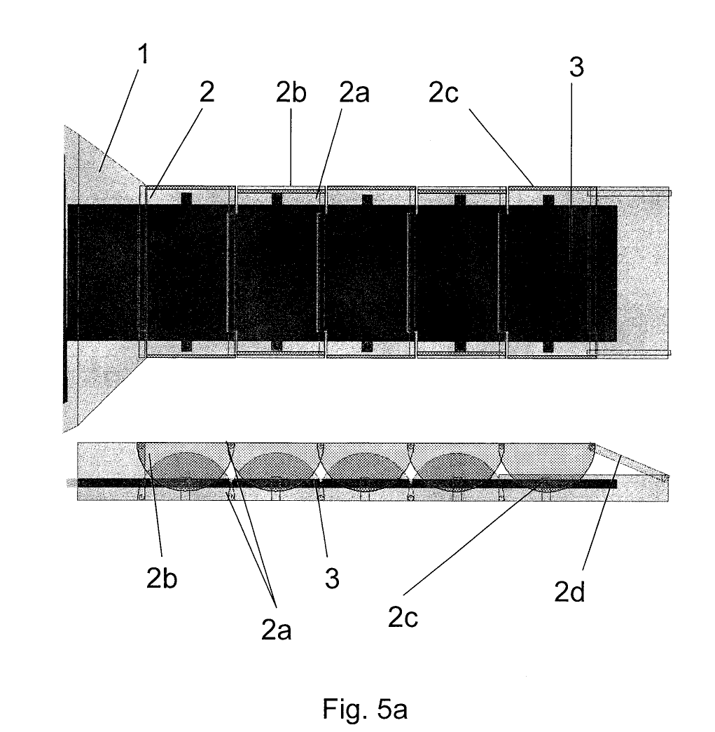

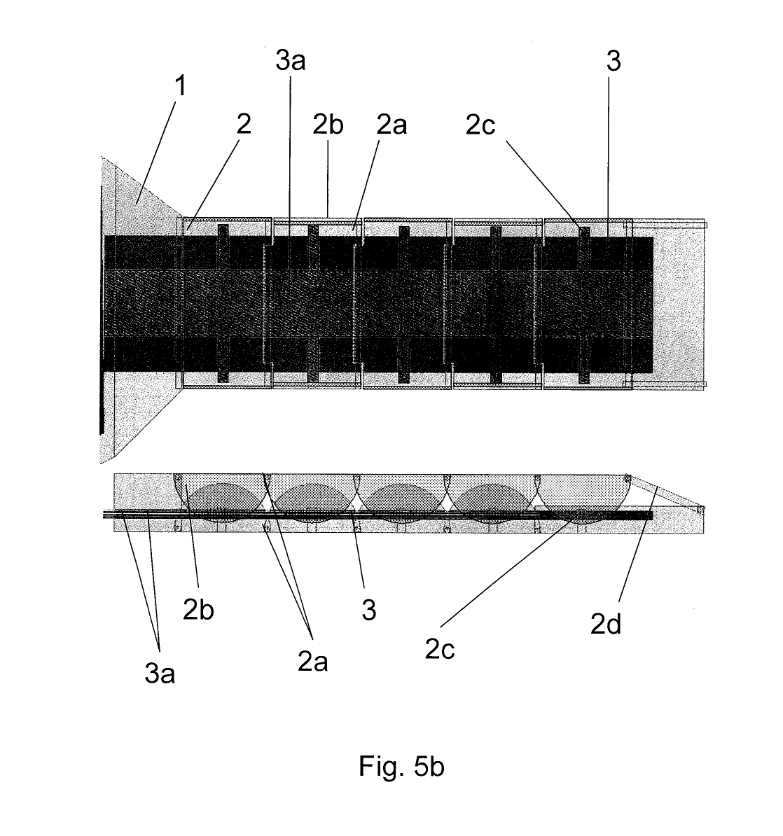

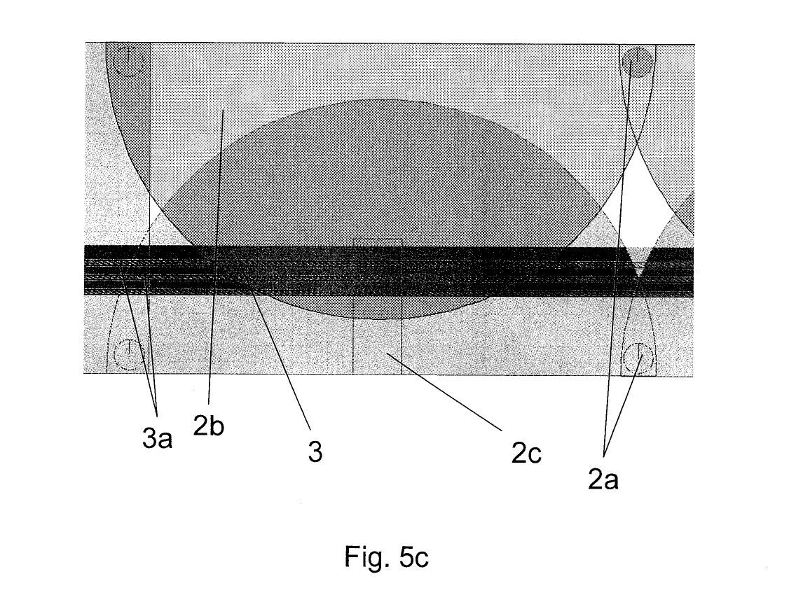

With reference to FIGS. 1 and 5 a,b and c, in this embodiment inside the rigid-flex printed circuit board 3 (only the flex film is shown for enhanced visual description) there is at least one (1) conductive layer 3a which is electrically and/or thermally connected with the metallic pins 2c to the metallic- case 1 and link 2 chains. In analog, alternatively, the conductive layer 3a could be directly electrically and/or thermally connected to the metallic case 1 (not shown).

There is further provided a rigid-flex printed circuit board 3, placed inside the metallic case and links, in order to mount electrical components and electrically connect them to each other making up the core of the interior electrical circuit. It is mechanically fixated and electrically connected to the metallic link 2 by having metallic pins 2c, which stem from the former having a direction ninety (90) degrees (upwards) in relation to the former. The rigid-flex printed circuit board 3 has matching holes, which edges are metallic and connected to at least one (1) of the rigid-flex printed circuit board 3 conductive layers 3a in order to electrically and/or thermally transfer/connect it to the exterior metallic link and case. Thus, the rigid-flex printed circuit board 3 connects thermally and electrically the electrical components to the exterior metallic case and links where the later functions either as a (i) thermal heat sink and electrical ground or (ii). cold source, where the former electrical components are the complementary (accumulative) heat sources (electrical components have a minimum working temperature of 50° C.) and, combined, make up a thermoelectric circuit connected to the power converter 46, which together with the CPU 10, battery 5 and power management IC 25 constitutes a energy management system; or (iii). a combination of the two above as the above mentioned holes in the rigid-flex printed circuit board 3 has the freedom in design to optimize the proportion of functioning as either a thermal heat sink (heat transferred from components) or cold source (relative cooler temperature source from the metallic case and links) by having a minimum of two separate conductive layers 3a in the rigid-flex printed circuit board 3 to be connected to different holes located along the metallic link. In yet another alternative, depending on the climate the user is located, the cold source could be chosen between being in the form of the (i). metallic case 1 and link 2 chains in thermal convection with ambient air (at temperatures below 37° C.) or (ii). in thermal contact with the user's skin (at ambient air temperatures over 37° C.). Where, in the latter case, the thermal connection is made in conjunction with the below mentioned sensor 33 or metallic pins 43.

Further, the rigid-flex printed circuit board 3 and its mounted electrical components (which do not need to interface with the exterior) is painted with a nonconductive, conformal coating. Commonly used conformal coatings are silicone, epoxy, acrylic, urethane and paraxylene. The function of the coating is to (i). prevent damage from rough user handling, (ii). reduction of mechanical and thermal stress as well as (iii). prolonging the lifetime of the components. Also to (iv). increase the dielectric strength between conductors lines on the rigid-flex printed circuit board 3 enabling the design of it to be more compact and small. Additionally it also functions to (v). align the directivity/thermal gradient vector of the heat generated from the respective components to the underlying thermal conductor line 3a in order to increase the heat obtained in the thermal conductor lines end and so maximizing the temperature difference in the thermoelectric circuit.

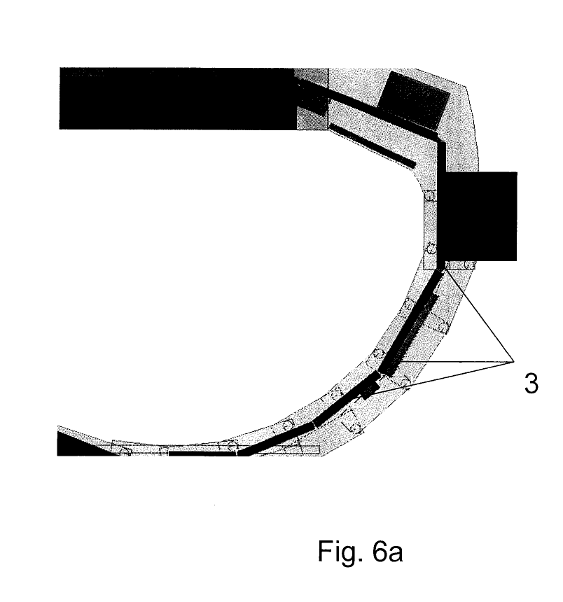

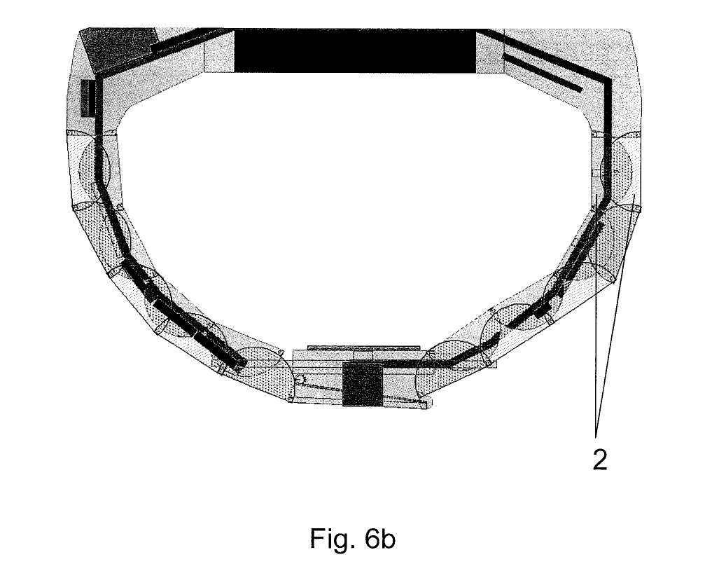

With reference to FIG. 6 a and b, in this embodiment the rigid-flex printed circuit board 3 and the metallic link 2 chain, flanking on both sides of the metallic case 1, obtain a final shape similar to a partial circle in order to mount it on a user's wrist similar to a ordinary wrist watch but with the significant difference of being made up of two rows of metallic link 2 chains instead of one.

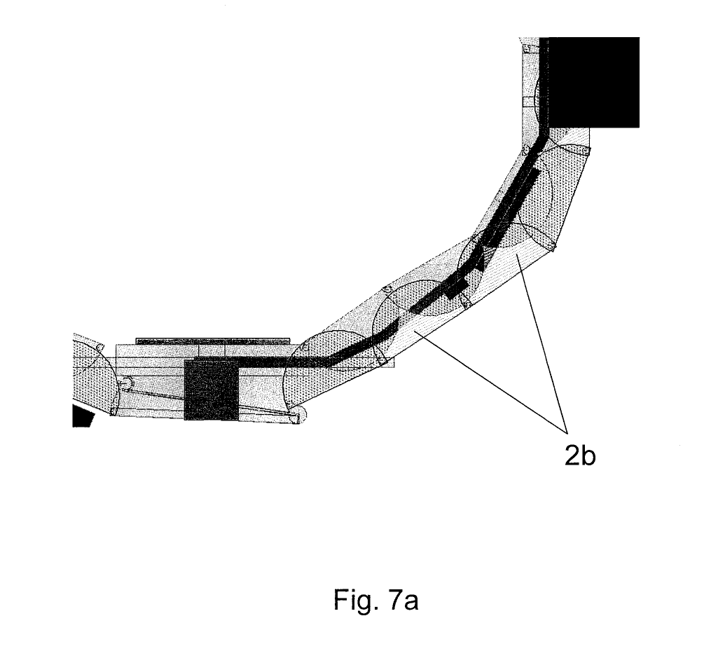

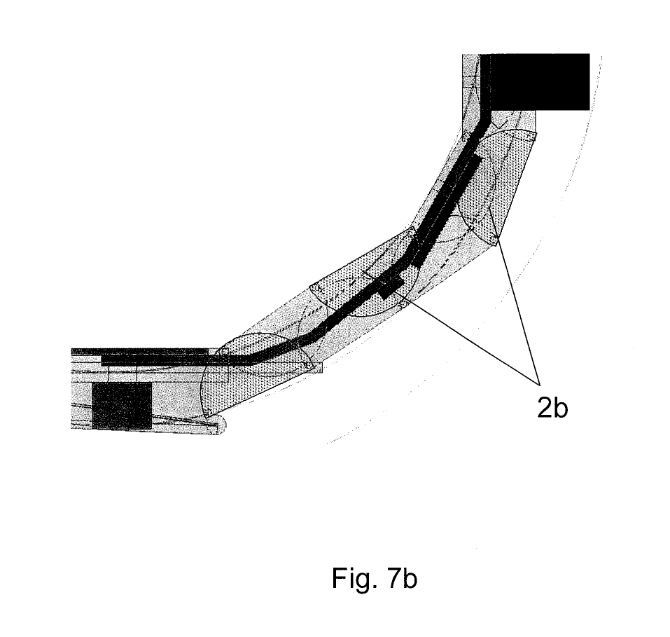

With reference to FIG. 7a, in this embodiment by having the upper row of semi-circled shaped metallic parts 2b obtain magnetic properties the neighbouring parts can position with different angles respective to each other; consequently the whole metallic link can obtain a final shape similar to a partial circle (i.e. similar shape as a wrist watch when mounted on user's wrist but with the significant difference of being made up of two rows of metallic links instead of one).

With reference to FIG. 7b, in this embodiment by having both the upper and lower rows of the semi-circled shaped metallic parts 2b, in an alternating order, obtaining magnetic properties; the neighbouring parts can position with different angles respective to each other; consequently the whole metallic link 2 chain acquires a final shape similar to a partial circle.

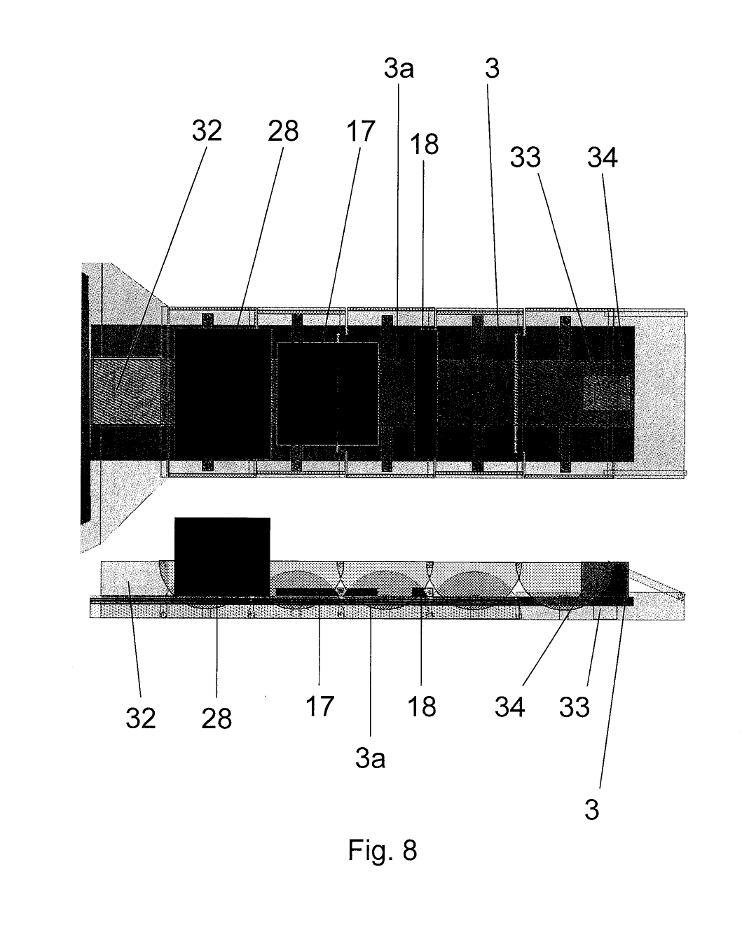

With reference to FIG. 8, in this embodiment there a multitude of electronic components mounted and electrically connected to the rigid-flex printed circuit board 3: an image sensor 32, a viewfinder display 28, a flash memory 17, a WLAN IC 18, a sensor 33 and a membrane 34. There respective ground potentials are electrically connected to at least one (1) conductive layer 3a inside/integrated the rigid-flex printed circuit board 3. Combined, or as an alternative, the respective electric components side facing inwards are thermally connected to at least one (1) conductive layer 3a inside/integrated the rigid-flex printed circuit board 3.

The electronic components are placed and positioned in such a way and order in order to optimize the handling and interaction of it with the user, which enhances the user with a higher degree of physical latitude.

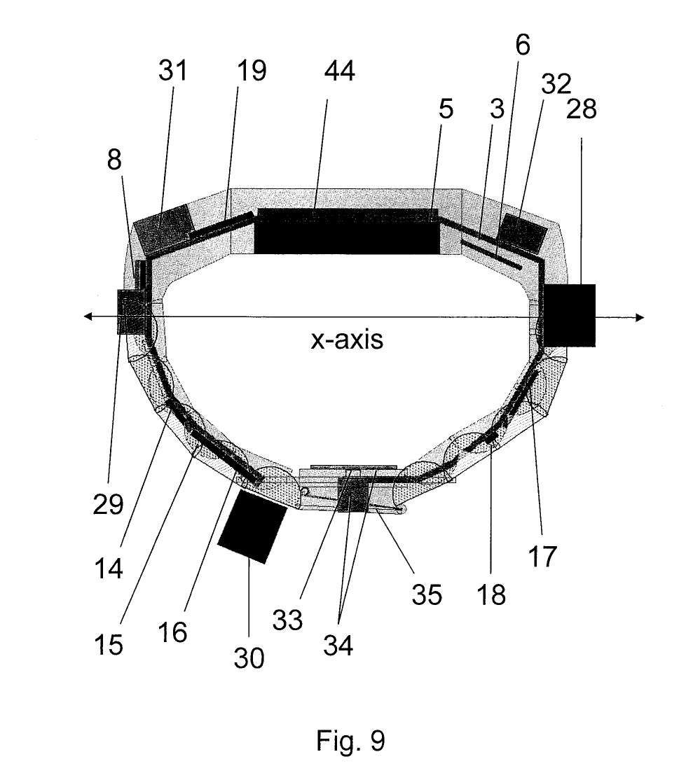

With reference to FIG. 9, in this embodiment the image sensor 32 and the viewfinder display 28 are positioned in such a way on adjacent sides of the metallic case 1 (or at its end) and placed in the metallic link 2 chains facing outwards. The placement described above of the respective electric components is along the same (x-axis) plane in order for the user to perceive the mobile wrist watch as a camera where the viewfinder display 28 and image sensor 32 normally are located along the same (x-) axis.

Additionally, there is provided a sensor 33 placed together with an accompanying membrane 34—which enhances its sensitivity—at the end of the rigid-flex printed circuit board 3 placed underneath the user's blood veins at the wrist facing inwards. Thus the users pulse can be monitored continuously for medical or health purposes. Alternatively, when using the above described viewfinder display 28 and image sensor 32 for photography or filming the sensor 33 can function as a snapshot/recording button (automatically adjusted to such usage by software alterations) handled by the users other hand's thumb (for example). The sensor 33 could be a pressure- or infrared sensor or a tensymeter (or its equivalent).

In order to lock and fixate the two ends of the metallic link 2 chains there is a locking mechanism 35 similar to an ordinary wrist watch.

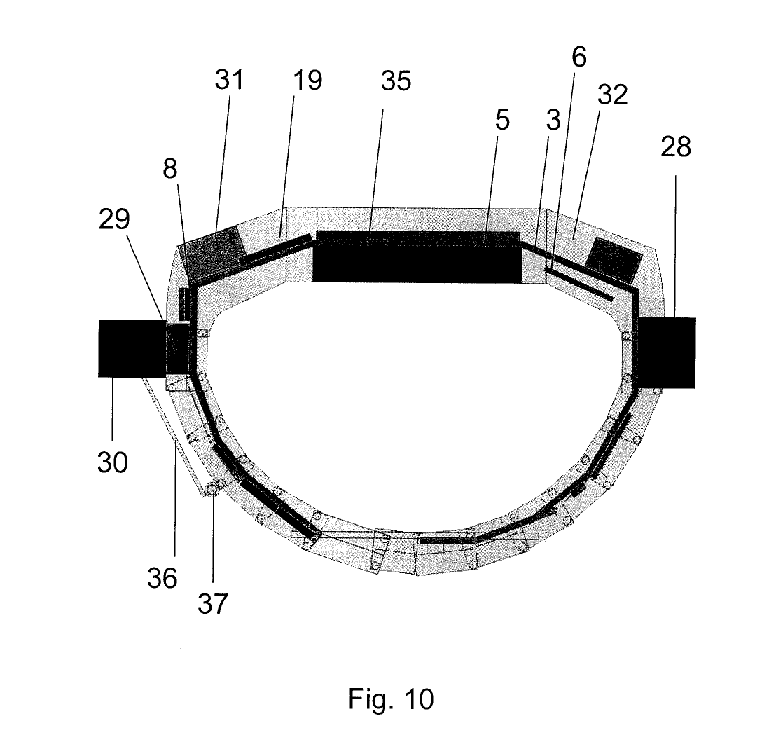

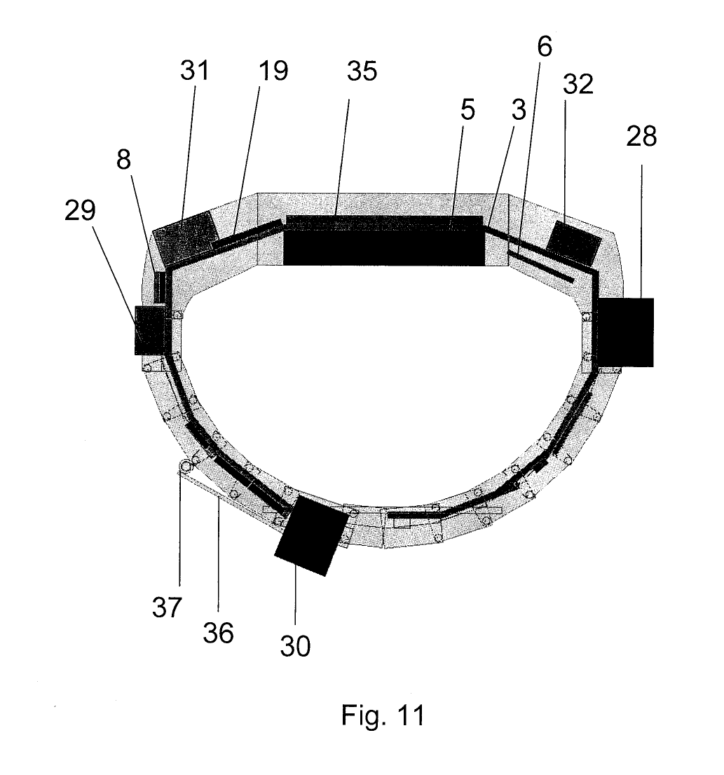

With reference to FIGS. 10 and 11, in this embodiment the image sensor 32 and the viewfinder display 28 are positioned in such a way on adjacent sides of the metallic case 1 (or at its end) and placed in the metallic link 2 chains facing outwards. The placement described above of the respective electric components is along the same (x-axis) plane in order for the user to perceive the mobile wrist watch as a camera where the viewfinder and image camera sensor normally are located along the same (x-) axis.

Additionally, on top of the image sensor an objective lens 30 is mounted (screwed) or fixated magnetically when more advanced photography or filming is needed. When not using the objective lens it can either be (i). placed elsewhere (pocket etc.) or, (ii). fixated to an arm 36 which can revolve around its (other) end 37—which is fixated to the metallic link—with more than a 200 degrees angle in order to place it in a protective position partly inside the metallic link.

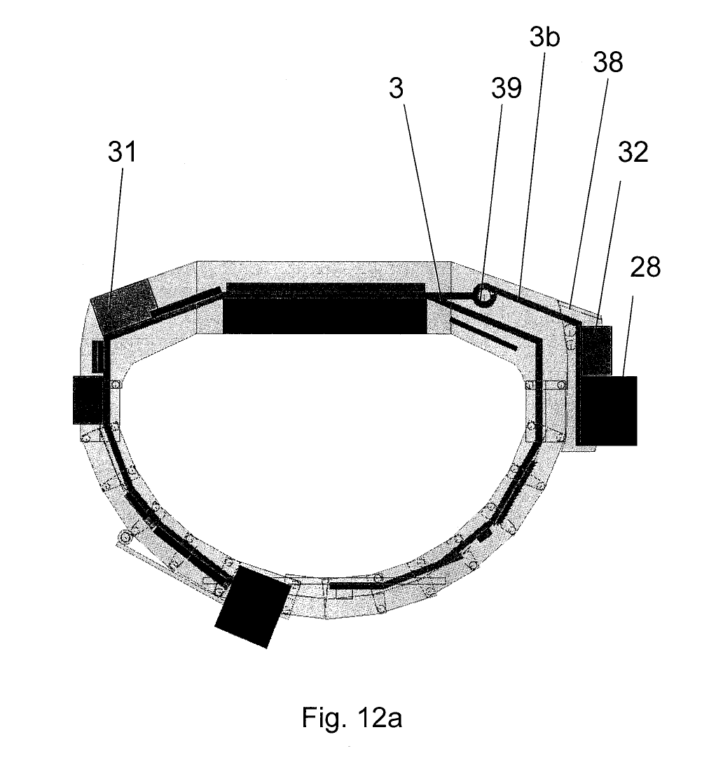

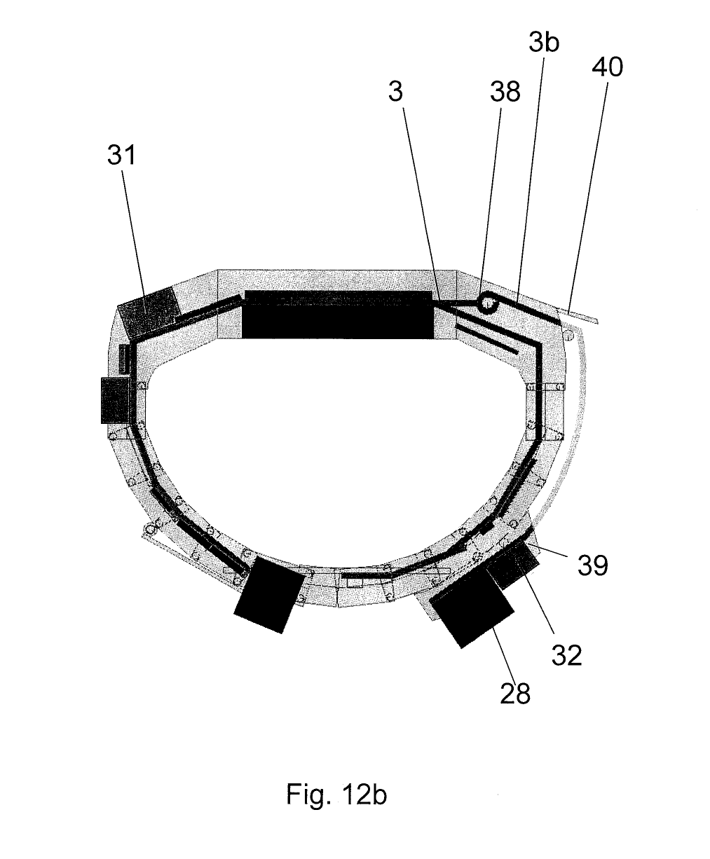

With reference to FIG. 12 a and b, in this embodiment, in order to enhance the user a higher degree of physical latitude when taking photos, filming or having a video conversation, the viewfinder display 28 and image sensor 30 are mounted mechanically on an exterior module 38 which can be moved along the metallic link 2 chain. Electrically they are connected to the electrical circuit by having a rollable flexible printed circuit board 3b which keeps it stretched independent of its desired length by a small tube 39. In its default position the exterior module 38 and rollable flexible printed circuit board 3b has a metallic shielding in the form of a roof 40 fixated to the metallic- case 1 or link 2.

Additionally, there is a projection device 31 mounted at one end alternatively, edge) of the metallic case 1 in order for the user to project images onto for the moment available physical areas (walls, floor, table etc.). When having a mobile video conversation the projection device 31 in combination with the above described image sensor 30—with or without the exterior module 38 alternative—it is simultaneously possible to obtain both a sufficiently good projection area and be able to position the image sensor optimally to acquire an image of the user's face.

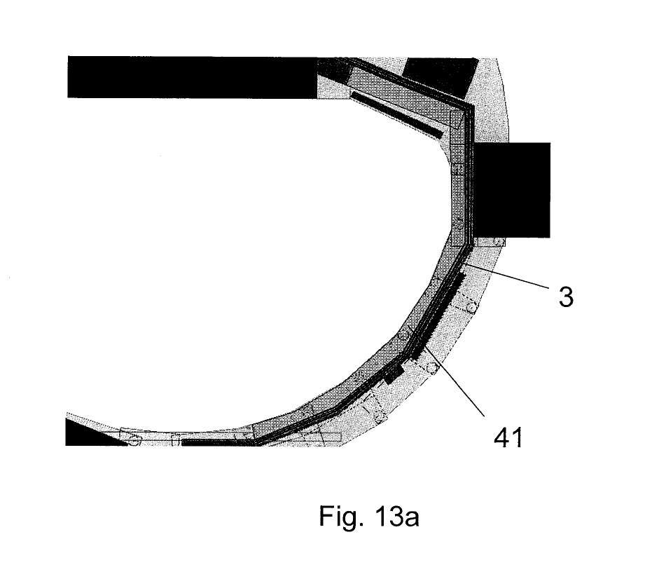

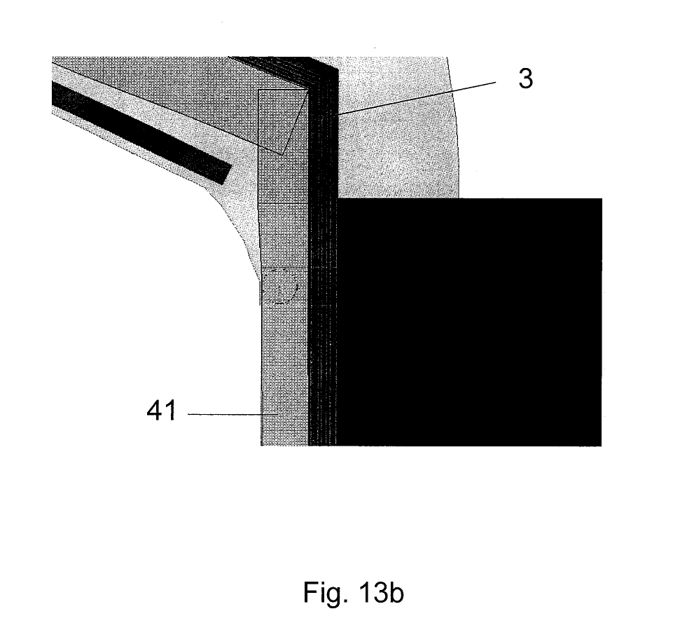

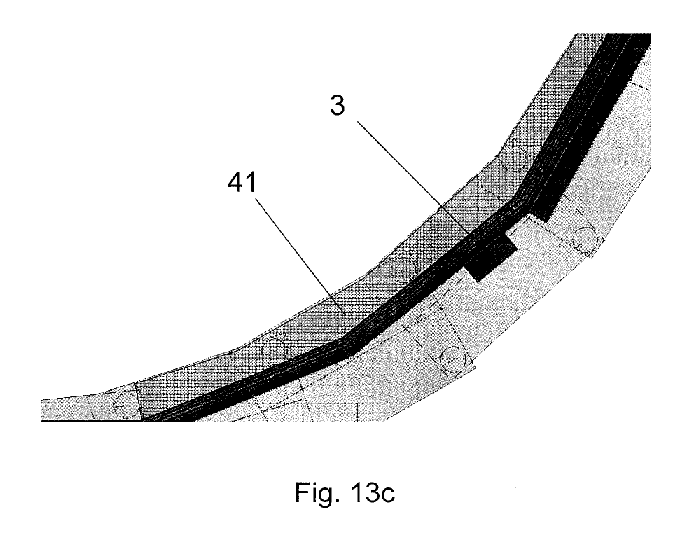

With reference to FIG. 13 a, b and c, in this embodiment a layer of conformal coating 41 consisting of a polymer with piezoelectric material (for example, pzt—lead zirconate titanate—or zinc oxide materials), which converts mechanical energy to electrical energy, called a piezoelectric circuit, is placed on one side of the rigid-flex printed circuit board 3 to provide electricity to the electrical components. At one end of the piezoelectric circuit it is connected electrically to the rigid-flex printed circuit board 3 and subsequently to the power converter 46 which together with the CPU 10, battery 5 and power management IC 25 constitutes a energy management system (not shown).

From the users arm motion mechanical energy between 1.5-6.7 Joule per movement translates to a power generated of 1.5-3.0 W. For a piezoelectric material with a 15 cm² area and a conversion efficiency of 11% this generates a harvested power in the 1-10 mW range (power density of 300 μW/cm²).

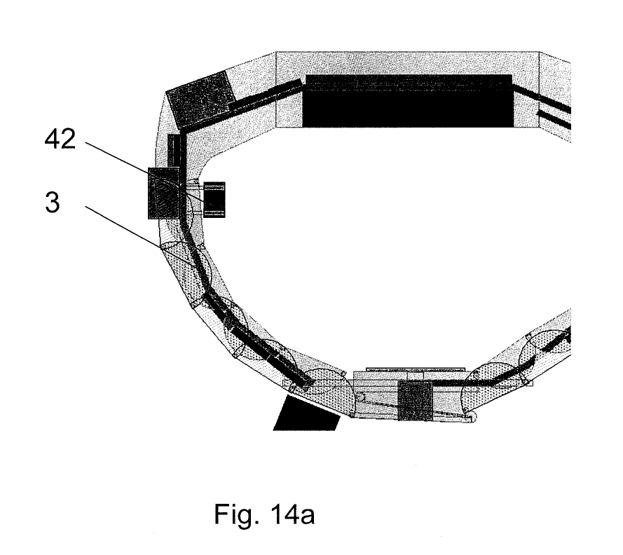

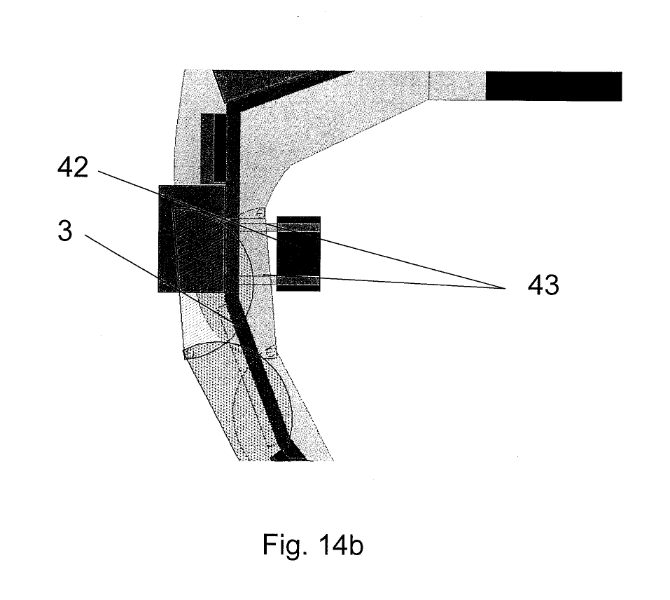

With reference to FIGS. 14 a and b, in this embodiment there is attached a medical sensor 42 (infrared-, reverse iontophoresis-) on the backside of the metallic link 2. Its purpose is to either (i). detect glucose or lactate levels noninvasively from the interstitial fluid in the subcutaneous tissue under the skin or (ii). monitor the conductivity of the skin.

The medical sensor can be placed in an opening in the centre of a transdermal tape (not shown). The sensor is mechanically and electrically fixed and connected by at least one (1) metallic pin 43 to the rigid-flex printed circuit board 3 and can therefore be easily replaced (when broken/low detectivity levels). The electrical circuit receiving the signal processes the data and presents the information on the screen to the user or is transferred wirelessly to remote location for monitoring or diagnostic purposes.

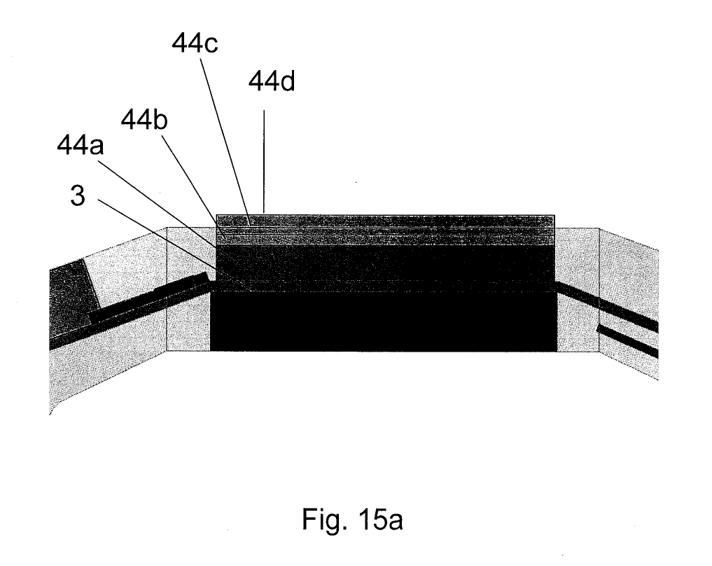

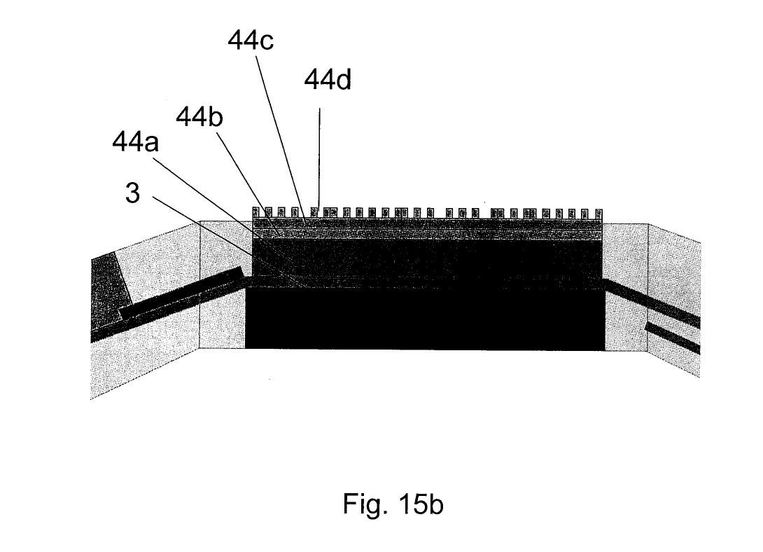

With reference to FIGS. 15 a and b, in this embodiment there is provided a top display 44a located in the centre of the metallic case facing outwards. It constitutes of different kinds of polymers, from top to bottom: (i). a shape memory polymer 44d (or an electro active polymer), which is controlled/triggered/induced by temperature, electric or magnetic field or light to change the physical topography and (ii). a lenticular lens polymer 44c, which produces images with an illusion of depth and (iii). organic light emitting diode 44b (oled) polymer, which is sandwiched between two conductors (an anode—for example, indium tin oxide (ITO) is transparent to visible light—and a cathode—metals such as barium and calcium) producing a bright, electro-luminescent light in a pixelated image arrangement. The exact layer configuration is designed to optimize optical and electrical conditions. For example, a spacer may be put inbetween the (i). organic light emitting diode 44b and lenticular lens polymer 44c and/or (ii). lenticular lens polymer 44c and shape memory polymer 44d, in order to optimize the optical distance and obtain desired visual image and/or physical shape.

Combining, or separately, the functionalities of the above described layers of polymers offers a wide range of physical shapes and 2- or 3 dimensional images which can simultaneously be created resulting in an increased esthetic user experience. The polymer composition can further be used to display and shape (i). Braille symbols, in order for blind people to receive realtime communication information or (ii). form a reduced (simple) keyboard with symbols in order for the user to communicate with simple text or numbers or (iii). display another person when performing a video conversation or (iv). display and physically animate a figure or picture to the user's liking (as, for example, being the default displayed image and physical shape when display is not in use).

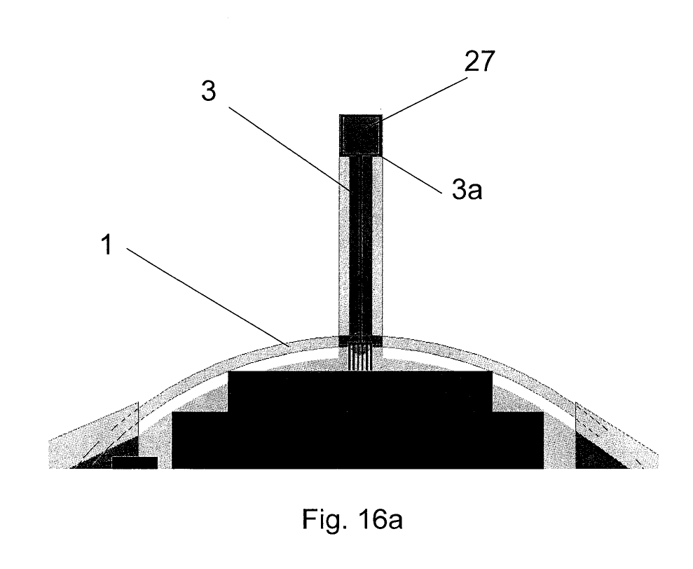

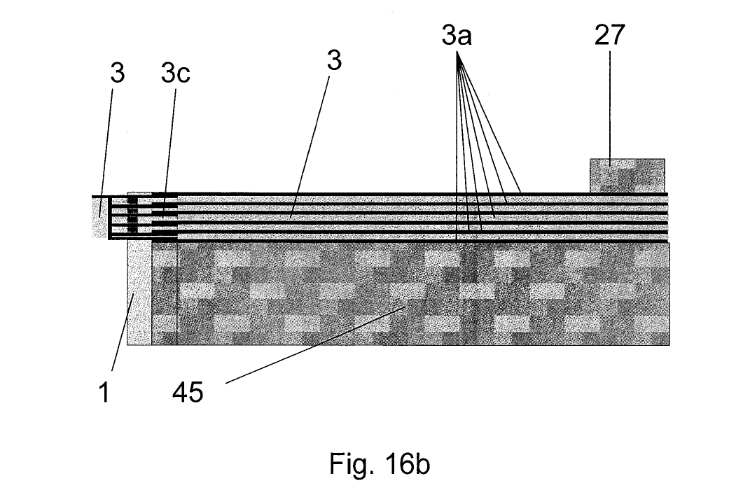

With reference to FIG. 16 a and b, in this embodiment there is provided a rigid, slightly curved cantilever beam 4 with an accelerometer 27 which at one end is fixated to the above mentioned exterior case and at the other end free standing. The accelerometer 27 is mounted on the free standing end and electrically connected to the rigid-flex printed circuit board 3 with a multitude of conductive layers 3a.

The rigid, slightly curved cantilever beam 4 is made of such a material so as to enhance it shape slightly curved downwards in contact with the user's central part of the hand. Additionally, the material robustness of the rigid cantilever beam is still flexible enough to adapt in height in order to follow the users vertical hand movements.

In order to electrically connect the accelerometer to the other parts of the electrical circuit, located in the above mentioned metallic case 1 and links 2 and at the same time be able to, when not used for monitoring hand tremor/movements, turn its free standing end to be protected by the metallic case 1, the fixated end needs to be able to rotate around its own x- and y-axis. Consequently, the rigid-flex printed circuit board 3 is made up of at least six (6) conductive layers placed on top of each other alternated with dielectric layers in between. The conductive layer 3a and the adjoining dielectric layer are at one end not attached to the adjacent equivalents but are hanging freely in order to be electrically connected to the rigid-flex printed circuit board 3 part located inside the metallic case 1 by mechanically pressing each parts of the rigid-flex printed circuit board 3 together and their respective layers in alternating order.

The accelerometer will function to detect (i). hand movements in its extended mode and (ii). arm movements in its inserted mode. Combined with an accelerometer mounted on the rigid-flex printed circuit board 3 inside the metallic case 1 (not shown) both hand- and arm movements can be detected at the same time to provide complementary relative measurements of hand tremor/movements.

Thus it can be used for monitoring tremor movements for medical diagnostics and/or gaming/steering devices and/or software available to the user.

Further, when not used for the above monitoring hand tremor/movements, the accelerometer can be used for monitoring arm movements for example, various gaming applications.

Further, a piezoelectric element can be integrated on the rigid-flex printed circuit board 3 to provide power by mechanical energy harvesting.

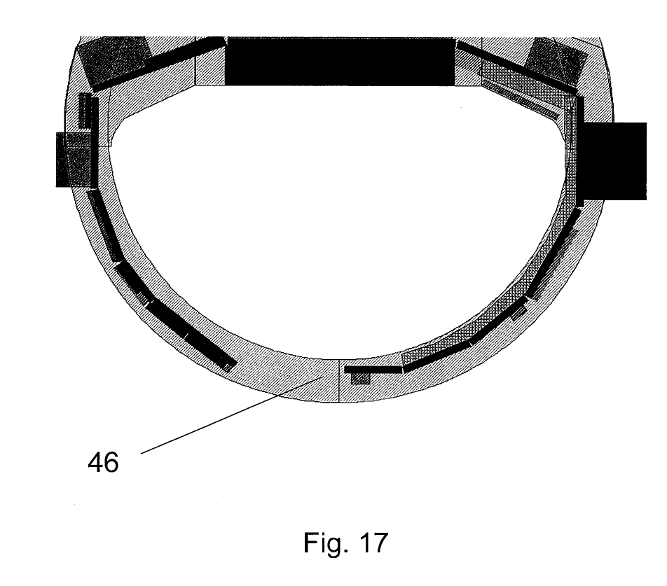

With reference to FIG. 17, in this embodiment as an alternative to the metallic link 2, which are made up of a multitude of metallic parts, there is a non-metallic, bendable (as opposed to made up of multiple parts) material 46 which encapsulates the electronic components mounted on the rigid-flex printed circuit board 3 all the while obtaining a final shape similar to a partial circle (i.e. similar shape as a wrist watch when mounted on user's wrist) protecting against physical or chemical damage from the exterior environment. The non-metallic, bendable material 46 could be made of for example plastic or rubber. As an esthetical attractive combination, on the exterior side of the non-metallic, bendable material 46 a layer of textile, leather or similar could be placed (with adhesive, for example).

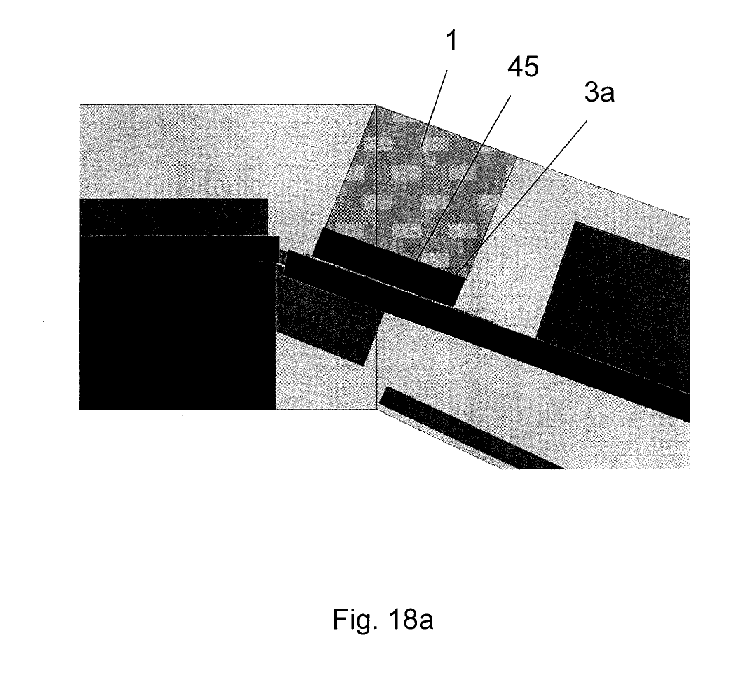

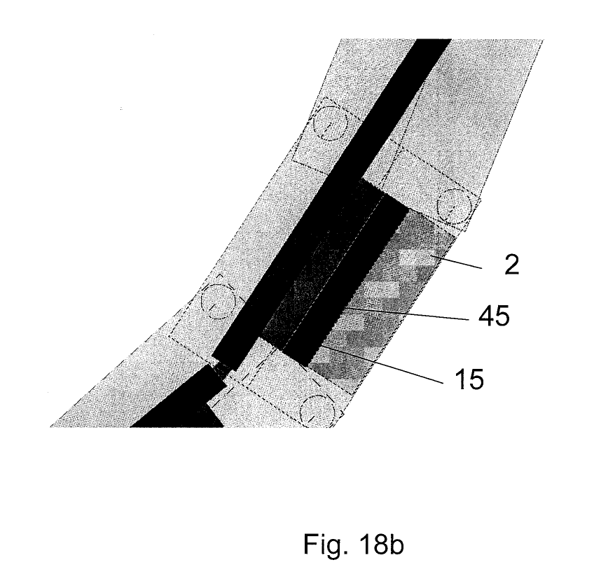

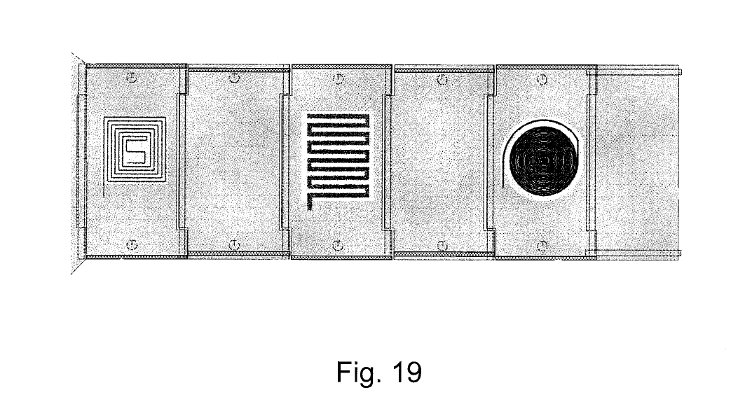

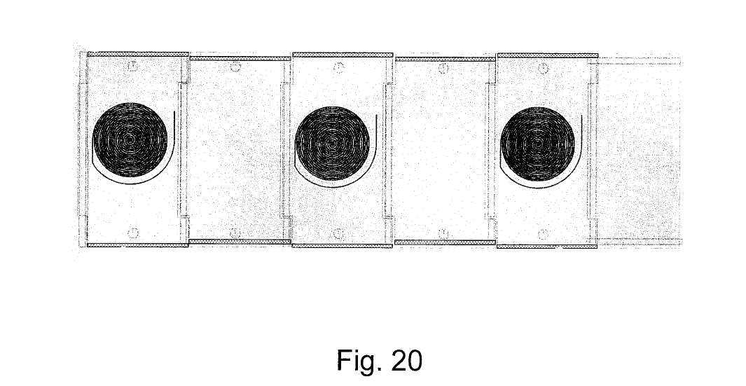

With reference to FIG. 18 a and b, in this embodiment there is at the end of atleast one conductive layer 3a a thermally connected metallic area on the top layer functioning as a heat spreader 47 which the thermoelectric generator (TEG) 45 is mounted on top in order to have a thermal connection between the two; on top of the thermoelectric generator (TEG) 45 the metallic case 1 is locally formed inwards in order to thermally connect to the former; the respective thermal connections constitutes the hot- and cold source respectively for the thermoelectric generator (TEG) 45.

Alternatively, the thermoelectric generator (TEG) 45 is mounted or integrated on top of each individual electronic component, for example a power amplifier 15, where the latter functions as the heat source. On the other, top side the metallic link 2 is locally formed inwards in order to thermally connect and thus function as the cold source for the thermoelectric generator (TEG) 45. On the electronic components facing outwards the thermoelectric generator (TEG) 45 could alternatively be mounted on the side and the metallic link 2 is from the side locally formed inwards in order to thermally connect (not shown).

Both solutions recycle power per component in the 10-100 mW range but the former with an order of magnitude less due to primarily thermal refraction.

The mobile wrist watch has herein been described mainly in the context of an accessorie comprising several electrical- and micromechanical components acting as a central processing unit for a multitude of tasks including mobile computing, imaging handling and medical sensing. However, it should be appreciated that many of the teachings disclosed herein are advantageous also when the mobile wrist watch is adapted for applications combining, in particular, a multitude of the sensors integrated.

For example, to monitor and diagnose the user's physical and physiological (emotional) state the accelerometers 24 and 27, the pressure (infrared)/temperature sensor 33 and medical sensor 42 obtain vital information like (i). low glucose levels relating to diabetes disease (ii). high lactate levels indicating of oxygen deprivation (iii). skin conductance indicating sympathetic activity (iv). body/skin temperature (v). pulse rate and pulse rate variability indicating heart rate and heart rate variability, respectively and systolic- and diastolic blood pressure (vi). conscious hand and/or arm motion to monitor movement (vii). unconscious hand and/or arm tremor movement; all these combined makes it possible for the CPU 10 to in real time process the data in order to conclude in what physical and/or physiological (emotional) state the user currently is in. Consequently, the combined data gives sufficient information to conclude the following (but not limited to): if the user is in an emotional state of (i). anger—higher skin conductance, highest pulse rate, decreasing pulse rate variability and highest diastolic blood pressure (ii). fear—higher skin conductance and—combined with a finger temperature monitor—significant change in finger temperature (iii). depression—low pulse rate and pulse rate variability, significant reduction in diastolic blood pressure (iv). Happiness—significant reduction in both pulse rate and skin conductance (v). stress—decreasing pulse rate variability.

This in turn makes it possible to use these combined sensor information for a wide variety of applications: (i). health/medical monitoring—for example, advanced physical aerobic training using lactate-, body temperature-, pulse rate- and arm movement sensors (ii). identification, electronic payment, pass card—for example, all health parameters give a unique, personal signature which, combined with an arm and/or hand movement (as well as or instead of a unique electronic chip inside the mobile wrist watch) an identification (iii). gaming—the health parameters can contribute as real time, online data used for the virtual profile's state of condition; additionally, the arm and hand motion sensors can be used as steering devices.

It should also be understood that the set of electronic and/or electromechanical components integrated in the mobile wrist watch may be easily adapted to the intended use of the mobile wrist watch. For example, the mobile wrist watch needs not to include an accelerometer or a pressure sensor when used for identification of the user wearing it. In this case, it may be sufficient to integrate a microcontroller (programmed with an identification number or the like) and the antenna circuitry in the mobile wrist watch.

Aspect 1: A Mobile Wristwatch comprising:
a metallic link (2) and metallic pin (2a) which are constituted of vibrational motors, which have the desired designed shape for mechanical-, electrical- and thermal functionalities when connected together obtaining a final shape similar to a partial circle (i.e. similar shape as a wrist watch when mounted on user's wrist).
   wherein the vibrational motors functions to accelerate the user's wrist towards different directions coupled to where the active vibration motor is located; used, for example, for gaming purposes (not shown).
   Aspect 2: A Mobile Wristwatch comprising:
a metallic link (2) which is fabricated with micro machined springs as resonating structures, which functions as vibration induced power generators.
   wherein they are designed in various shapes in order to simultaneously function optimally for both electrical and esthetical purposes (FIG. 19 and FIG. 20).
   Aspect 3: A Mobile Wristwatch comprising:
a metallic link (2) which is fabricated with openings in order to mount a stator and actuators, and on top a rotor,
   wherein they combined functions as small electrical rotating motors (not shown).
   Aspect 4: A Mobile Wristwatch comprising:
an electronic interface connection on its inner, left side (in respect to the user left hand, where it is worn) which facilitates a physical and electrical connection to where a mountable keyboard temporarily can be placed by the user in order for him or her to write text messages reminiscent of an ordinary keyboard
   wherein the keyboard is physically placed so to have its weight on the users arm in order to have a temporarily physical stand facilitating the writing texting procedures.
   Aspect 5: A Mobile Wristwatch comprising:
a thermometer, constituted of a Cu/CuNi alloy deposited on top of a dielectric layer, which combined are integrated alongside the backside edge of the metallic case (1) and connected to the rigid-flex printed circuit board (3) in order to measure and monitor the skin temperature on the user (not shown).
   Aspect 6: A Mobile Wristwatch comprising:
an ECG monitoring functionality consisting of, in combination with another physical entity with electronics integrated—for example an electronic fingering—worn on the other hands finger, measuring a voltage potential—in the range of 1 μV to 0.9 V—across the heart/chest region and upper limbs to detect heart arrhythmias in order to identify atrial fibrillation
   wherein the overall purpose is to monitor and predict and avoid stroke as well as and other related coronary heart failures.
   Aspect 7: A Mobile Wristwatch comprising:
microphone components integrated alongside the frontside edge of the metallic case (1) and connected to the rigid-flex printed circuit board (3) in order to detect sounds of the user or the surrounding environment (not shown).
   Aspect 8: A Mobile Wristwatch comprising:
an electronic interface connection on its outer, right side (in respect to the user left hand, where it is worn) which facilitates a physical and electrical connection to a wireless earpiece
   wherein the purpose is to store it there while the user is not communicating or listening wirelessly with the said mobile wristwatch, thus communicating with far and nearby electronic devices wirelessly with established radiofrequency technologies.
   Aspect 9: A Mobile Wristwatch comprising:
infrared light emitting diode and infrared sensor components mounted on and connected to the rigid-flex printed circuit board (3) in order to measure and monitor the reflecting light from the blood veins of the user, functioning as an oximeter (not shown) which together with a pressure sensor (33), measuring the pulse and additionally combined with a microphone can monitor sleeping apnea in a superior way as oxygen levels, pulse rate and breathing sound levels can continuously be monitored.

1. A mobile wrist watch for communication, comprising:
an exterior of a metallic case (1) and links (2), where the links are made up of a multitude of metallic parts, being made up of two rows of metallic links, which are connected in the horizontal direction mechanically and in the vertical/radial direction magnetically;
a rigid-flex printed circuit board (3), mounted with electrical components which is mechanically fixated and electrically connected to the metallic case and links
and combined, form a thermoelectric circuit.

2. The mobile wrist watch according to claim 1, wherein only the outer metallic links (2), which are semi circled shaped and connected in the vertical/radial direction, obtain magnetic properties, in order for the parts to position with different angles respective to each other and consequently obtain a final shape similar to an ordinary wrist watch, to minimize any magnetic flux radiated from the same onto the electric components located inside the metallic link chain.

3. The mobile wrist watch according to claim 1, wherein every odd metallic link (2), which are connected in the vertical/radial direction, are connected magnetically in order for the parts to position with different angles respective to each other and consequently obtain a final shape similar to an ordinary wrist watch.

4. The mobile wrist watch according to claim 1, wherein there are a multitude of square shaped rings enclosing alongside the two above mentioned rows of metallic links (2), which move freely along the horizontal length bounded/limited by pegs on each individual square shaped ring's sides.

5. The mobile wrist watch according to claim 1, wherein on the metallic links (2) a plastic surface finish by injection moulding is deposited.

6. The mobile wrist watch according to claim 1, wherein the metallic links (2) have metallic pins (2c), which stem from the former, directed ninety (90) degrees upwards.

7. The mobile wrist watch according to claim 1, wherein the metallic links (2) have a plastic film (47) placed on its interior side stretched along the metallic links (2) accumulated length ending inside the metallic case (1) which function is to waterproof electrical components and could be in a form of a bag.

8. The mobile wrist watch according to claim 1, wherein the rigid-flex printed circuit board (3) has holes located along its sides, which circumference edges are metallic and connected to at least one of the rigid-flex printed circuit board's conductive layers (3a) in order to electrically and/or thermally transfer/connect it to the exterior metallic case (1) and links (2).

9. The mobile wrist watch according to claim 1 and 5, wherein the exterior metallic case (1) and links (2) functions as a thermal heat sink and electrical ground.

10. The mobile wrist watch according to claim 1, 5 and 6, wherein the exterior metallic case (1) and links (2) functions as a combination of both a cold source and thermal heat sink thermally connected to the electrical components on the rigid-flex printed circuit board (3) having a minimum of two separate conductive layers (3a) in the rigid-flex printed circuit board being connected to different holes located along the metallic link (2).

11. The mobile wrist watch according to claim 1, where inside the rigid-flex printed circuit board (3) there is at least one conductive layer (3a) which is electrically and/or thermally connected with the metallic pins (2c) to the metallic- case (1) and link (2) chains.

12. The mobile wrist watch according to claim 1, the conductive layer 3a could be directly electrically and/or thermally connected to the metallic case 1.

13. The mobile wrist watch according to claim 1, wherein the rigid-flex printed circuit board (3) and its mounted electrical components are painted with a nonconductive, conformal coating where the latter functions to align the directivity of the heat generated from the respective components to the underlying thermal conductor line (3a) in order to increase the heat obtained in the same.

14. The mobile wrist watch according to claim 1, wherein there is a rigid, slightly curved cantilever beam (45), at one end fixated to the exterior metallic case (1) and at the other end free standing, mounted with an accelerometer (27).

15. The mobile wrist watch according to claim 1 and 14, wherein the rigid, slightly cantilever beam (45) is flexible enough in its vertical direction in order to adapt its height or curvature and thus follow a users vertical hand movements and monitor the user's tremor movement of his or her hand.

16. The mobile wrist watch according to claim 1, 14 and 15, wherein the free standing accelerometer (27) is connected to the electrical circuit by having a flexible printed circuit board made up of at least six (6) conductive layers placed on top of each other alternated with dielectric layers in between.

17. The mobile wrist watch according to claim 1 and 9, wherein there is an additional accelerometer (27) mounted inside the metallic case (1) or links (2) in order to provide additional, comparative measurement data.

18. The mobile wrist watch according to claim 1, wherein there is a medical sensor (42) mounted on the backside/inner exterior of the metallic links (2) which is mechanically and electrically fixed and connected by metallic pins (43) to the rigid-flex printed circuit board 3 inside the metallic case (1) and links (2) and wherein the said sensor is placed in the centre of an medical (transdermal) tape in order to detect glucose- or lactate levels noninvasively from the interstitial fluid in the subcutaneous tissue or monitor the skin conductivity.

19. The mobile wrist watch according to claim 1, wherein there is a viewfinder display (28) placed in the metallic case (2) or link (3) facing outwards.

20. The mobile wrist watch according to claims 1 and 19, wherein there is an image camera sensor (29) placed, on the adjacent side of the metallic case, in the metallic link facing outwards; in such a way so the viewfinder display (28) and image camera sensor (29) is along the same (x-axis) plane.

21. The mobile wrist watch according to claim 1, and 20, wherein there is an objective lens (30) which is mounted or fixated magnetically on top of an image sensor (29).

22. The mobile wrist watch according to claim 1, 20 and 21, wherein the objective lens (30) is fixated to an arm (36) which revolves around one end and fixated at the other end (37) to the metallic link (2) protecting the former partly when positioned inside the latter.

23. The mobile wrist watch according to claim 1, 19 and 20, wherein the above mentioned viewfinder (28) is mounted mechanically on an exterior module (39) which moves along the metallic link (2) and is electrically connected to the electrical circuit by a rollable flexible printed circuit board (3b) keeping the latter stretched independent of its length.

24. The mobile wrist watch according to claims 1, 19, 20 and 23, wherein the above mentioned viewfinder (28) has a metallic shielding (40) in the form of a roof fixated to the metallic case (1) or link (2).

25. The mobile wrist watch according to claims 1, 20 and 23 wherein there is a combination of a projection device (31) mounted at one end of the metallic case (1) and an image sensor (29) mounted inside the above described exterior, movable module (39), along with the viewfinder (28), to optimize the simultaneous projection and image acquiring during a mobile video conversation.

26. The mobile wrist watch according to claim 1 wherein there is a pressure sensor (33) located at the end of the rigid-flex printed circuit board (3) facing inwards in order to continuously monitor the pulse of the user.

27. The mobile wrist watch according to claim 1, 14-21 wherein there is a temperature sensor (not shown) located at the end of the rigid-flex printed circuit board (3) facing inwards in order to continuously monitor the temperature of the user.

28. The mobile wrist watch according to claim 1, 19-24 wherein the above mentioned pressure sensor (33) alternatively functions as a snapshot/recording button when used for photography or filming.

29. The mobile wrist watch according to claim 1 wherein there is a top display (44a) located in the top region of the metallic case (1) constituted of three different types of polymers, from top to bottom: a (i). shape memory (44d) (ii). lenticular lens (44c) and (iii). organic light emitting diode (oled) (44b), to, combined or separately, obtain physically or virtually a wide range of physical shapes and images which simultaneously results in (i). an increased esthetic user experience (ii). Braille symbols, in order for blind people to receive realtime communication information or (iii). form a reduced (simple) keyboard with symbols in order for the user to communicate with simple text or numbers or (iv). display another person when performing a video conversation or (v). display and physically animate a figure or picture to the user's liking.

30. The mobile wrist watch according to claim 1 wherein as an alternative to the metallic link (2), there is a non-metallic, bendable material (46) which encapsulates the electronic components mounted on the rigid-flex printed circuit board (3) all the while obtaining a final shape similar to a partial circle protecting against physical or chemical damage from the exterior environment.

31. The mobile wrist watch according to claim 1 and 30 wherein the non-metallic, bendable material (46) is made of plastic or rubber, where on its exterior side, a layer of textile or leather is mounted.

32. The mobile wrist watch according to claim 1, 8, 11 and 12 wherein there is at the end of at least one conductive layer (3a) a thermally connected metallic area on the top layer functioning as a heat spreader (47) which the thermoelectric generator (45) is mounted on top in order to have a thermal connection between the two; additionally, on top of the thermoelectric generator (45), the metallic case (1) is locally formed inwards in order to thermally connect to the former; where the respective thermal connections constitutes the hot- and cold source respectively for the thermoelectric generator (45).

33. The mobile wrist watch according to claim 1, 8, 11 and 12 wherein the thermoelectric generator (45) is mounted or integrated on top of each individual electronic component where the latter functions as a heat source; additionally, on the other, top side the metallic link (2) is locally formed inwards in order to thermally connect and thus function as the cold source for the thermoelectric generator (45).

34. The mobile wrist watch according to claim 1 wherein the order and placement/positioning of the electronic components along the metallic link (2) are of significant importance in order for their individual tasks to serve the overall purpose to provide additional degrees of physical latitude for the user.

35. The mobile wrist watch according to claim 1 wherein it performs tasks of mobile computing, imaging handling, medical monitoring and communicating with far and nearby electronic devices wirelessly with established radiofrequency technologies.
